(19) United States
(12) Patent Application Publication
(10) Pub. No.: US 2025/0218893 A1
(43) Pub. Date: Jul. 3, 2025

(54) ENGAGING CONNECTION STRUCTURE AND ENGAGING CONNECTION METHOD THEREOF

(71) Applicant: FIVETECH TECHNOLOGY INC., New Taipei City (TW)

(72) Inventor: TING-JUI WANG, New Taipei City (TW)

(73) Assignee: FIVETECH TECHNOLOGY INC., New Taipei City (TW)

(21) Appl. No.: 18/805,574

(22) Filed: Aug. 15, 2024

(30) Foreign Application Priority Data
Dec. 28, 2023 (TW) 112151328

(51) Int. Cl. H01L 23/40; F16B 5/10

(52) U.S. Cl. CPC H01L 23/40; F16B 5/10

(57) ABSTRACT

An engaging connection structure and an engaging connection method thereof are introduced. The engaging connection structure includes an engaging body provided with a first engaging portion and a second engaging portion. The first engaging portion is for rotating after inserting through or passing through a receiving portion of an engaged body, for the second engaging portion to engagingly connect an engaged portion of the engaged body. Accordingly, with the coordination of the first engaging portion and the second engaging portion of the engaging body, quick coupling and separation of at least two objects can be completed to achieve effects of repeatedly quick coupling and separation.

### CROSS-REFERENCE TO RELATED APPLICATION

This non-provisional application claims priority under 35 U.S.C. § 119 (a) on Patent Application No(s). 112151328 filed in Taiwan, R.O.C. on Dec. 28, 2023, the entire contents of which are hereby incorporated by reference.

### BACKGROUND OF THE INVENTION

### 1. Field of the Invention

The present disclosure relates to an engaging connection structure and an engaging connection method thereof, and in particular to an engaging connection structure for engagingly connecting at least two objects to achieve quick coupling and easy removal and an engaging connection method thereof.

### 2. Description of the Related Art

In general, to couple two objects, a screw is usually locked therein to fix the two objects in a form that is not easily separated, thereby ensuring stable coupling between the two objects so that the two are unlikely to be detached from each other.

In the fixing means above, although the two objects can be fixed and coupled in a form that is not easily separated, in addition to unhandy assembly, these two objects may not be easily removed due to the fixed coupling means using the screw.

### BRIEF SUMMARY OF THE INVENTION

On the basis of at least one embodiment of the present disclosure, the present disclosure provides an engaging connection structure and an engaging connection method thereof. With the coordination of a first engaging portion and a second engaging portion of an engaging body, quick coupling and separation of at least two objects can be completed to achieve effects of repeatedly quick coupling and separation.

To achieve the above and other objects, the present disclosure provides an engaging connection structure. The engaging connection structure includes an engaging body provided with a first engaging portion and a second engaging portion. The first engaging portion is for rotating after inserting through or passing through a receiving portion of an engaged body, for the second engaging portion to engagingly connect an engaged portion of the engaged body.

The present disclosure further provides an assembly method for an engaging connection structure. The first engaging portion is for rotating after inserting through or passing through a receiving portion of the engaged body, for the second engaging portion to engagingly connect the engaged portion.

Optionally, a body is further included. The engaging body is movably disposed at the body, or the body is provided with an elastic element and two ends of the elastic element are respectively abutted against the engaging body and the body, or wherein the second engaging portion is elastically engaged into the engaged portion of the engaged body by elasticity of the elastic element.

Optionally, a body is further included. The engaging body is movably disposed at the body, the body is provided with a limiting portion and a rotation space, the engaging body further includes a head, the head is provided with an alignment portion, and the alignment portion is limited and moves at the limiting portion, for the first engaging portion to enter the receiving portion of the engaged body and the alignment portion to rotate in the rotation space, further for the second engaging portion to engagingly connect the engaged portion.

Optionally, the body is provided with an assembly portion. The assembly portion is provided with an anti-rotation portion, and the anti-rotation portion is for preventing rotation, limiting a position or restricting a direction of an object, or the anti-rotation portion restricts a direction of the first engaging portion or the second engaging portion, or the anti-rotation portion corresponds to the limiting portion and the alignment portion to restrict a direction of the first engaging portion or the second engaging portion.

Optionally, the rotation space is a 360-degree full-circumferential structure, or the rotation space is a non-360-degree non-full-circumferential structure.

Optionally, the limiting portion, the rotation space or the alignment portion is a protrusion, a recess, a planar body, an arched body, a curved body, a block, a hole, a ring or a sectional body.

Optionally, a body is further included. The engaging body is movably disposed at the body, the body is provided with an elastic element, and two ends of the elastic element are respectively abutted against the engaging body and the body.

Optionally, the second engaging portion is elastically engaged into the engaged portion of the engaged body by elasticity of the elastic element.

Optionally, a body is further included. The engaging body is movably disposed at the body, the body is provided with an assembly portion, and the assembly portion is for riveting, engagingly connecting, expansion connecting, welding or locking to the object, or the assembly portion is integrally formed at the object.

Optionally, the engaging body is provided with a head. The head is assembled with the engaging body by an assembling portion, or the head and the engaging body are formed integrally, or wherein the engaging body is provided with a head and is for rotating the head for the second engaging portion to engagingly connect the engaged portion.

Optionally, the engaging body is provided with a head, and the head is rotated for the second engaging portion to engagingly connect the engaged portion.

Optionally, the engaging body is provided with a head and a body. The engaging body is movably disposed at the body, the head is first rotated to locate the second engaging portion at an engaging connection position corresponding to the engaged portion, the head is then turned or pulled to change a position of the head on the body, for the second engaging portion to engagingly connect the engaged portion.

Optionally, an object is included. The object is a heat dissipating body, a heat generating body is provided between the object and the engaged body, the engaging body applies a pressure with coordination of an elastic element on the heat dissipating body, for the heat dissipating body to be attached to the heat generating body so as to dissipate heat.

Optionally, the heat generating body is an integrated circuit (IC), a central processing unit (CPU), a graphics processing unit (GPU), a memory, a chip or a battery, or the engaged body is a circuit board, a metal body, a plastic body, or the heat generating body is assembled at the engaged body by welding or engaging connection or by a connector.

Optionally, a body is included. The engaging body is movably disposed at the body, the engaging body is provided with an alignment portion, the body is provided with a limiting portion and a rotation space, the rotation space has a height distance for motion or movement of the alignment portion, or the limiting portion has a height distance for motion or movement of the alignment portion, or a distance of engaging connection of the second engaging portion toward the engaged portion is equal to or less than the height distance of the rotation space, or a maximum distance of the first engaging portion inserting through or passing through the engaged body is equal to or less than the height distance of the limiting portion and the height distance of the rotation space.

Optionally, the first engaging portion or the second engaging portion is T-shaped, L-shaped, close to T-shaped or close to L-shaped, or the assembly of the first engaging portion and the second engaging portion is T-shaped, L-shaped, close to T-shaped or close to L-shaped.

Optionally, the engaged body is an iron part, a plastic part, a printed circuit board (PCB), a heat sink, an integrated circuit (IC), a memory, a water cooling element, a handle, a fan, a power supply device, a main casing, a cabinet, a computer or a data center.

### BRIEF DESCRIPTION OF THE DRAWINGS

To better describe the embodiments of the present disclosure or the technical solutions of the prior art, the accompanying drawings needed for and used in the description of the embodiments are described concisely below. It is obvious that the accompanying drawings in the description below provide merely some embodiments of the present disclosure, and a person of ordinary skill in the art could arrive at other accompanying drawings on the basis of these accompanying drawings without involving inventive skills.

FIG. 1 is a schematic diagram according to a first specific embodiment of the present disclosure.

FIG. 2 is a schematic diagram according to a second specific embodiment of the present disclosure.

FIG. 3 is a schematic diagram according to a third specific embodiment of the present disclosure.

FIG. 4 is a schematic diagram according to a fourth specific embodiment of the present disclosure.

FIG. 5 is a schematic diagram according to a fifth specific embodiment of the present disclosure.

FIG. 6 is a schematic diagram according to a sixth specific embodiment of the present disclosure.

FIG. 7 is a schematic diagram according to a seventh specific embodiment of the present disclosure.

FIG. 8 is a schematic diagram according to the seventh specific embodiment of the present disclosure.

FIG. 9 is a schematic diagram according to an eighth specific embodiment of the present disclosure.

FIG. 10 is a schematic diagram according to a ninth specific embodiment of the present disclosure.

FIG. 11 is a schematic diagram according to a tenth specific embodiment of the present disclosure.

FIG. 12 is a schematic diagram according to an eleventh specific embodiment of the present disclosure.

FIG. 13 is a schematic diagram according to a twelfth specific embodiment of the present disclosure.

FIG. 14 is a schematic diagram according to a thirteenth specific embodiment of the present disclosure.

FIG. 15 is a schematic diagram according to a fourteenth specific embodiment of the present disclosure.

### DETAILED DESCRIPTION OF THE INVENTION

An engaging connection structure of embodiments of the present disclosure are further described in detail with the accompanying drawings below.

The above and other technical contents, features and effects of the present disclosure can be clearly presented in the detailed description of the preferred embodiments in conjunction with the accompanying drawings below. It should be noted that, directional terms used in the embodiments below, for example, upper, lower, left, right, front and back are described with reference to the directions of the accompanying drawings. Thus, the directional terms are for illustration purposes and are not to be construed as limitations to the present disclosure. Moreover, in the embodiments below, the same or similar elements are denoted with the same or similar numerals or symbols.

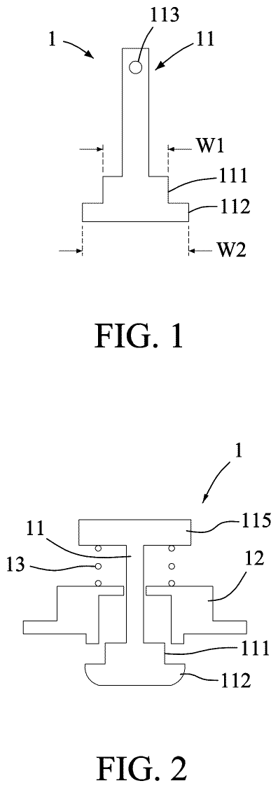

Referring to FIG. 1, as shown in the drawing, the present disclosure relates to an engaging connection structure 1 and an engaging connection method thereof. The engaging connection structure 1 at least includes: an engaging body 11, including a first engaging portion 111 and a second engaging portion 112. The first engaging portion 111 is for rotating after inserting through (or passing through) a receiving portion 102 of an engaged body 10, for the second engaging portion 112 to engagingly connect an engaged portion 101 of the engaged body 10. The first engaging portion 111 and the second engaging portion 112 can be engaged at the engaged portion 101 of the same engaged body 10 or the engaged portions 101 of different engaged bodies 10. Accordingly, with the coordination of the first engaging portion 111 and the second engaging portion 112 of the engaging body 11, quick coupling and separation of at least two objects can be completed to achieve effects of repeatedly quick coupling and separation.

On the basis of the embodiment above, in an assembly method of an engaging connection structure of the present disclosure, the engaging body 11 can be operated for the first engaging portion 111 to insert through (or to pass through) the receiving portion 102 of the engaged body 10, and then the engaging body 11 is rotated for the second engaging portion 112 to be engagingly connected the engaged portion 101. Thus, with the coordination of the first engaging portion 111 and the second engaging portion 112 of the engaging body 11, quick coupling and separation of at least two objects can be completed to achieve effects of repeatedly quick coupling and separation.

In one embodiment of the present disclosure, a width w1 of the first engaging portion 111 can be greater than a width w2 of the second engaging portion 112, the first engaging portion 111 and the second engaging portion 112 are located at a bottom of the engaging body 11, and the engaging body 11 is provided with an assembling portion 113 on a top thereof, wherein the assembling portion 113 can be for assembling related components, thereby enabling the present disclosure to better meet actual application requirements.

In one embodiment of the present disclosure, the engaged body 10 can be an iron part, a plastic part, a printed circuit board (PCB), a heat sink, an integrated circuit (IC), a memory, a water cooling element, a handle, a fan, a power supply device, a main casing, a cabinet, a computer or a data center, thereby enabling the present disclosure to better meet actual application requirements.

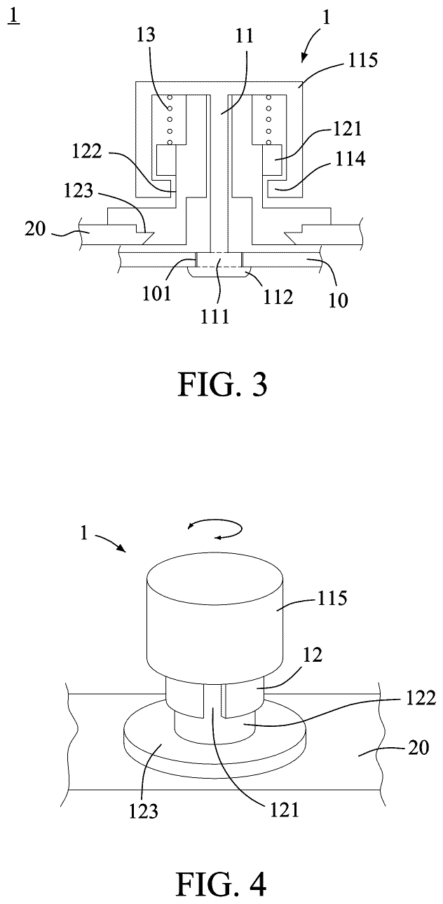

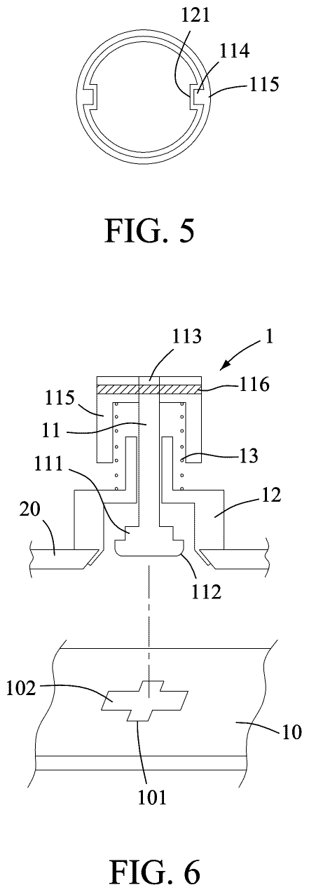

Referring to FIG. 2 to FIG. 5, as shown in the drawings, in one embodiment of the present disclosure, the engaging connection structure 1 further includes a body 12, and the engaging body 11 is movably disposed at the body 12. The body 12 is provided with an elastic element 13, two ends of the elastic element 13 are respectively abutted against the engaging body 11 and the body 12, the second engaging portion 112 is elastically engaged into the engaged portion 101 of the engaged body 10 by elasticity of the elastic element 13. Thus, with the coordination of the elastic element 13, the engaging body 11 of the engaging connection structure 1 enables the second engaging portion 112 to be engagingly connected to the engaged portion 101 securely.

In one embodiment of the present disclosure, the body 12 is provided with a limiting portion 121 and a rotation space 122, the engaging body 11 further includes a head 115, the head 115 is provided with an alignment portion 114, and the alignment portion 114 is limited and moves at the limiting portion 121, for the first engaging portion 111 to enter the receiving portion 102 of the engaged body 10, for the alignment portion 114 to rotate in the rotation space 122, and further for the second engaging potion 112 to engagingly connect the engaged portion 101.

In one embodiment of the present disclosure, the body 12 is provided with an assembly portion 123, and the assembly portion 123 is for riveting, engagingly connecting, expansion connecting, welding or locking to an object 20, or the assembly portion 123 is integrally formed the object 20.

In one embodiment of the present disclosure, the engaging body 11 is provided with a head 115, and the head 115 is rotated for the second engaging portion 112 to engagingly connect the engaged portion 101.

On the basis of the embodiment above, the engaging connection structure 1 can be assembled at the object 20 by using the assembly portion 123 of the body 12, the head 115 of the engaging body 11 is operated for the first engaging portion 111 to insert through (or pass through) the engaged portion 101 of the engaged body 10, and then the engaging body 11 is rotated for the second engaging portion 112 to be elastically engagingly connected to the engaged portion 101 by elasticity of the elastic element 13. Thus, with the coordination of the first engaging portion 111 and the second engaging portion 112 of the engaging body 11, quick coupling and separation of at least two objects can be completed to achieve effects of repeatedly quick coupling and separation.

Referring to FIG. 6 to FIG. 8, as shown in the drawings, in one embodiment of the present disclosure, the head 115 is assembled with the engaging body 11 by a bolt 116 with coordination of the assembling portion 113.

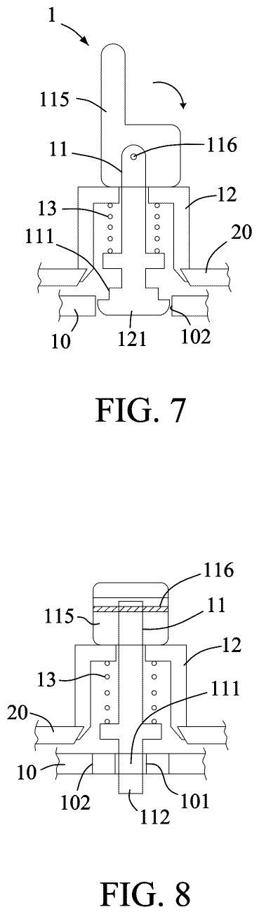

When in use (as shown in FIG. 7 and FIG. 8), the head 115 can first be rotated to locate the second engaging portion 112 at an engaging connection position corresponding to the engaged portion 101, the head 115 is turned or pulled to change the position of the head 115 on the body 12, for the first engaging portion 111 to insert through (or to pass through) the engaged portion 101 of the engaged body 10, and for the second engaging portion 112 to engagingly connect the engaged portion 101. Thus, with the coordination of the first engaging portion 111 and the second engaging portion 112 of the engaging body 11, quick coupling and separation of at least two objects can be completed to achieve effects of repeatedly quick coupling and separation.

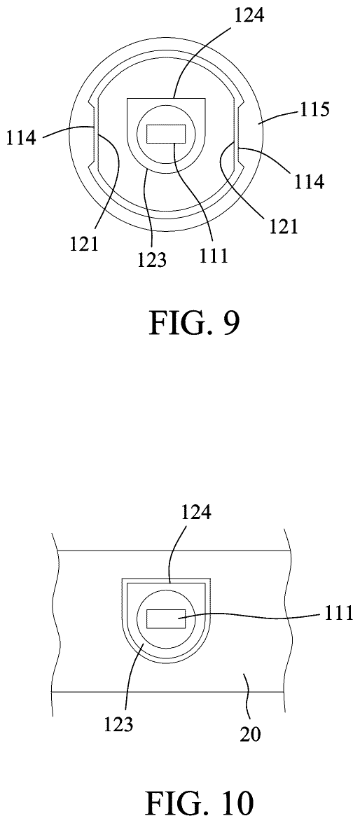

Referring to FIG. 9 to FIG. 11, as shown in the drawings, in one embodiment of the present disclosure, the assembly portion 123 is provided with an anti-rotation portion 124, which is for preventing rotation, limiting a position or restricting a direction of the object 20, thereby enabling the present disclosure to better meet actual application requirements.

In one embodiment of the present disclosure, the anti-rotation portion 124 can restrict a direction of the first engaging portion 111 or the second engaging portion 112, thereby enabling the present disclosure to better meet actual application requirements.

In one embodiment of the present disclosure, the anti-rotation portion 124 corresponds to the limiting portion 121 and the alignment portion 114 so as to restrict a direction of the first engaging portion 111 or the second engaging portion 112, thereby enabling the present disclosure to better meet actual application requirements.

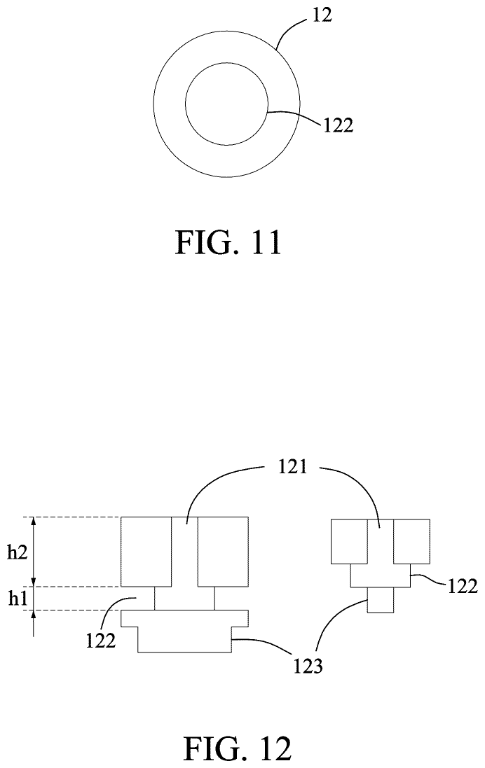

In one embodiment of the present disclosure, the rotation space 122 is a 360-degree full-circumferential structure (as shown in FIG. 11), or the rotation space 122 is a non-360-degree non-full-circumferential structure, thereby enabling the present disclosure to better meet actual application requirements.

In one embodiment of the present disclosure, the limiting portion 121, the rotation space 122 or the alignment portion 114 can be a protrusion, a recess, a planar body, an arched body, a curved body, a block, a hole, a ring or a sectional body, thereby enabling the present disclosure to better meet actual application requirements.

Referring to FIG. 12, as shown in the drawing, in one embodiment of the present disclosure, the rotation space 122 has a height distance h1 for motion or movement of the alignment portion 114, the limiting portion 121 has a height distance h2 for motion or movement of the alignment portion 114, a distance of engaging connection of the second engaging portion 112 toward the engaged portion 101 is equal to (or less than) the height distance h1 of the rotation space 122, a maximum distance of the first engaging portion 111 inserting through (or passing through) the engaged body 10 is equal to (or less than) the height distance h2 of the limiting portion 121 and the height distance h1 of the rotation space 122. Thus, the first engaging portion 111 can insert through (or pass through) the engaged portion 101 of the engaged body 10, and is then engagingly connected to the engaged portion 101 by the second engaging portion 112, so as to complete quickly coupling and separation of at least two objects to achieve effects of repeatedly quick coupling and separation.

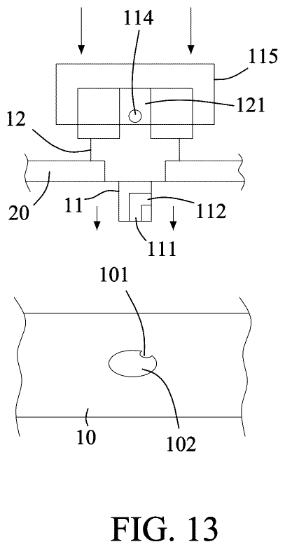

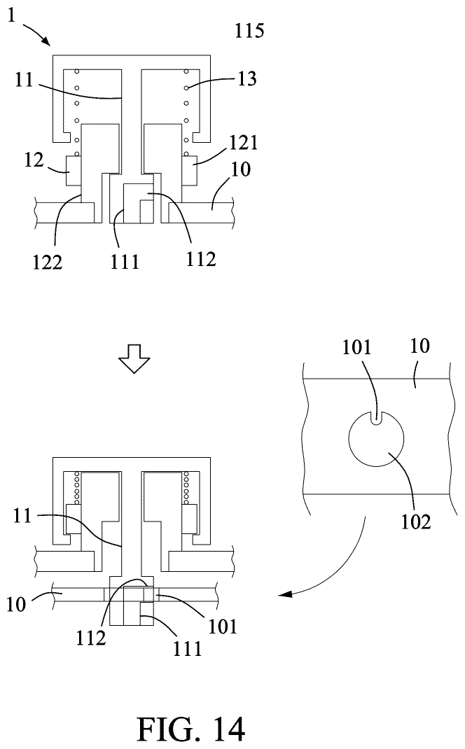

Referring to FIG. 13 and FIG. 14, as shown in the drawings, in one embodiment of the present disclosure, the first engaging portion 111 or the second engaging portion 112 can be T-shaped, L-shaped, close to T-shaped or close to L-shaped, or the assembly of the first engaging portion 111 and the second engaging portion 112 can be T-shaped, L-shaped, close to T-shaped or close to L-shaped, thereby enabling the present disclosure to better meet actual application requirements.

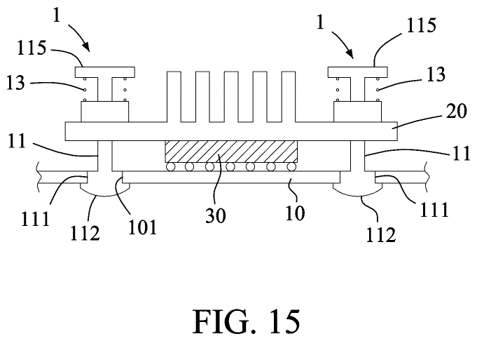

Referring to FIG. 15, as shown in the drawing, in one embodiment of the present disclosure, the object 20 can be a heat dissipating body, a heat generating body 30 is provided between the object 20 and the engaged body 10, the engaging body 11 is engagingly connected to the engaged portion 101 of the engaged body 10 by the first engaging portion 111 and the second engaging portion 112 and at the same time applies a pressure with coordination of the elastic element 13 on the object (the heat dissipating body), for the object 20 (the heat dissipating body) to be securely attached to the heat generating body 30 so as to dissipate heat.

In one embodiment of the present disclosure, the heat generating body 30 can be an integrated circuit (IC), a central processing unit (CPU), a graphics processing unit (GPU), a memory, a chip or a battery, the engaged body 10 can be a circuit board, a metal body, a plastic body, and the heat generating body 30 is assembled at the engaged body 10 by welding or engaging connection or by a connector, thereby enabling the present disclosure to better meet actual application requirements.

In conclusion, with the coordination of the first engaging portion and the second engaging portion of an engaging body, the engaging connection structure and the engaging connection method thereof according to the present disclosure are capable of completing quick coupling and separation of at least two objects so as to achieve effects of repeatedly quick coupling and separation.

It should be noted that the description above is merely the embodiments of the present disclosure and is not to be construed as limitations to the scope of the claims of the present disclosure.

What is claimed is:

1. An engaging connection structure, comprising an engaging body comprising a first engaging portion and a second engaging portion, the first engaging portion is for rotating after inserting through or passing through a receiving portion of an engaged body, for the second engaging portion to engagingly connect an engaged portion of the engaged body.

2. The engaging connection structure according to claim 1, further comprising a body, wherein the engaging body is movably disposed at the body, or the body is provided with an elastic element, two ends of the elastic element are respectively abutted against the engaging body and the body, or wherein the second engaging portion is elastically engaged into the engaged portion of the engaged body by elasticity of the elastic element.

3. The engaging connection structure according to claim 1, further comprising a body, wherein the engaging body is movably disposed at the body, the body is provided with a limiting portion or a rotation space, or the engaging body further comprises a head, or the head is provided with an aligning portion, or the aligning portion is limited and moves at the limiting portion, or for the first engaging portion to enter the receiving portion of the engaged body and for the aligning portion to rotate in the rotation space, for the second engaging portion to engagingly connect the engaged portion.

4. The engaging connection structure according to claim 3, wherein the body is provided with an assembly portion, or the assembly portion is provided with an anti-rotation portion, or the anti-rotation portion is for preventing rotation, limiting a position or restricting a direction of an object, or the anti-rotation portion restricts a direction of the first engaging portion or the second engaging portion, or the anti-rotation portion corresponds to the limiting portion and the alignment portion to restrict a direction of the first engaging portion or the second engaging portion.

5. The engaging connection structure according to claim 3, wherein the rotation space is a 360-degree full-circumferential structure, or the rotation space is a non-360-degree non-full-circumferential structure.

6. The engaging connection structure according to claim 3, wherein the limiting portion, the rotation space or the alignment portion is a protrusion, a recess, a planar body, an arched body, a curved body, a block, a hole, a ring or a sectional body.

7. The engaging connection structure according to claim 1, wherein the engaging body is movably disposed at the body, or the body is provided with an assembly portion, or the assembly portion is for riveting, engagingly connecting, expansion connecting, welding or locking to an object, or the assembly portion is integrally formed at the object.

8. The engaging connection structure according to claim 1, wherein the engaging body is provided with a head, the head is assembled with the engaging body by an assembling portion, or the head and the engaging body are formed integrally, or wherein the engaging body is provided with a head and is for rotating the head for the second engaging portion to engagingly connect the engaged portion.

9. The engaging connection structure according to claim 1, wherein the engaging body is provided with a head and a body, the engaging body is movably disposed at the body, the head is first rotated to locate the second engaging portion at an engaging connection position corresponding to the engaged portion, the head is then turned or pulled to change a position of the head on the body, for the second engaging portion to engagingly connect the engaged portion.

10. The engaging connection structure according to claim 1, further comprising an object, wherein the object is a heat dissipating body, or a heat generating body is provided between the object and the engaged body, or the engaging body applies a pressure with coordination of an elastic element on the heat dissipating body, for the heat dissipating body to be attached to the heat generating body so as to dissipate heat, or wherein the heat generating body is an integrated circuit (IC), a central processing unit (CPU), a graphics processing unit (GPU), a memory, a chip or a battery, or the engaged body is a circuit board, a metal body, a plastic body, or the heat generating body is assembled at the engaged body by welding or engaging connection or by a connector.

11. The engaging connection structure according to claim 1, further comprising a body, wherein the engaging body is movably disposed at the body, the engaging body is provided with an alignment portion, or the body is provided with a limiting portion and a rotation space, or the rotation space has a height distance for motion or movement of the alignment portion, or the limiting portion has a height distance for motion or movement of the alignment portion, or a distance of engaging connection of the second engaging portion toward the engaged portion is equal to or less than the height distance of the rotation space, or a maximum distance of the first engaging portion inserting through or passing through the engaged body is equal to or less than the height distance of the limiting portion and the height distance of the rotation space.

12. The engaging connection structure according to claim 1, wherein the first engaging portion or the second engaging portion is T-shaped, L-shaped, close to T-shaped or close to L-shaped, or the assembly of the first engaging portion and the second engaging portion is T-shaped, L-shaped, close to T-shaped or close to L-shaped.

13. The engaging connection structure according to claim 1, wherein the engaged body is an iron part, a plastic part, a printed circuit board (PCB), a heat sink, an integrated circuit (IC), a memory, a water cooling element, a handle, a fan, a power supply device, a main casing, a cabinet, a computer or a data center.

14. An assembly method for an engaging connection structure, using the engaging connection structure of claim 1, wherein the first engaging portion is for rotating after inserting through or passing through a receiving portion of the engaged body, for the second engaging portion to engagingly connect the engaged body.
